(19) United States
(12) Patent Application Publication
(10) Pub. No.: US 2026/0107417 A1
(43) Pub. Date: Apr. 16, 2026

(54) Cold Plate Cooling Device

(71) Applicant: Chenming Electronic Technology Corporation, Taipei City (TW)

(72) Inventors: Shin Lee, Taipei City (TW); Chuan-Li Cheng, Taipei CIty (TW)

(21) Appl. No.: 19/328,585

(22) Filed: Sep. 15, 2025

(30) Foreign Application Priority Data
Oct. 16, 2024 (TW) 113211170

(51) Int. Cl. H05K 7/20

(52) U.S. Cl. CPC H05K 7/20772

(57) ABSTRACT

The present disclosure provides a cold plate cooling device, which includes a water tank, a cold plate, a branching pipe, a water pump and a heat exchanger. The cold plate body is in contact with a heat generating component, and the coolant in the cold plate body dissipates the heat from the heat generating component. The coolant inlet is connected to the cold plate outlet, and the cold plate is positioned higher than the water tank. The branching pipe includes a main pipeline and a side pipeline. The main pipeline is connected to the circulating waterway outlet, and the side pipeline is connected to the coolant outlet. The coolant flows from the water tank through the main pipeline, the water pump and the heat exchanger, and returns to the water tank, forming a continuous circulating waterway. When the continuous circulating waterway flows through the main pipeline, negative pressure is generated in the side pipeline so that the coolant flows from the water tank into the cold plate body, dissipates the heat and enters the main pipeline through the side pipeline, forming a cold plate negative pressure circuit.

### CROSS-REFERENCE TO RELATED APPLICATION

This application claims the benefit of Taiwan Patent Application No. 113211170, filed on October 16, 2024, in the Taiwan Intellectual Property Office, the disclosure of which is incorporated herein in its entirety by reference.

### BACKGROUND OF THE INVENTION

### 1. Field of the Invention

The present disclosure relates to a cold plate cooling device, and in particular to a cold plate cooling device that utilizes a branching pipe to form a negative pressure inlet to prevent coolant leakage from damaging heat generating components.

### 2. Description of the Related Art

With the development of technologies such as the Internet and artificial intelligence, the demand for servers and cloud computing devices continues to increase. As computing power increases, the heat generated by the processing units or computing units of these devices during operation also increases. The way to effectively dissipate heat from these devices has become a critical issue. In addition to installing air conditioning in the installment for cool down, these specific heat generating components such as processing units or computing units must be provided with more effective cooling devices to prevent these electronic components from burnout due to high temperatures or affecting computing performance.

Among various cooling options, water-cooled cooling devices offer superior heat dissipation and are often chosen for servers and computer equipment. Conventional water-cooled cooling devices typically use a water pump to pump coolant into a cold plate, and after heat exchange occurs with the heat generating components, the coolant removes the heat and achieves the heat dissipation effect. However, if joints or surface cracks occur within these water-cooled cooling devices, the positive pressure from the water pump may cause the coolant to leak through these cracks, and if such coolant comes into contact with electronic components, it could cause a short circuit or burnout, damaging the operation of the electronic device.

In light of the above, the design of existing water-cooled heat dissipation devices still has considerable shortcomings. It is difficult to prevent coolant leakage when gaps or holes appear in the structure, which may easily damage the heat generating components. Consequently, the inventors of the present disclosure have designed a cold plate cooling device to solve these shortcomings and enhance its industrial application.

### SUMMARY OF THE INVENTION

In view of the above-mentioned shortcomings of the conventional technology, the objective of the present disclosure is to provide a cold plate cooling device to solve the problem of coolant leakage in conventional water-cooled cooling devices and to prevent damage dealt to heat generating components.

According to one of the objectives of the present disclosure, a cold plate cooling device is provided, which includes a water tank, a cold plate, a branching pipe, a water pump and a heat exchanger. Wherein, the water tank includes a water tank inlet, a tank body, a cold plate outlet and a circulating waterway outlet. The cold plate includes a coolant inlet, a cold plate body, and a coolant outlet, wherein the cold plate body is in contact with a heat generating component, and a coolant in the cold plate body dissipates heat from the heat generating component, the coolant inlet is connected to the cold plate outlet, and the cold plate is positioned higher than the water tank. The branching pipe includes a main pipeline and a side pipeline, wherein the main pipeline is connected to the circulating waterway outlet, and the side pipeline is connected to the coolant outlet, and the water pump is connected to the main pipeline. The heat exchanger includes a hot water inlet, a heat exchange chamber and a cold water outlet, wherein the hot water inlet is connected to the water pump, and the cold water outlet is connected to the water tank inlet. The coolant flows out from the tank body through the circulating waterway outlet to the main pipeline, being pumped out by the water pump and sent to the hot water inlet, and then flows out from the cold water outlet and returns to the water tank through the water tank inlet, forming a continuous circulating waterway, and when the continuous circulating waterway flows through the main pipeline, negative pressure is generated in the side pipeline so that the coolant flows out from the cold plate outlet, flows into the cold plate body through the coolant inlet, and then flows out from the coolant outlet and enters the main pipeline through the side pipeline, forming a cold plate negative pressure circuit.

Preferably, the water tank may be disposed at a bottom of the cold plate cooling device.

Preferably, the heat exchanger may be disposed at a higher position than the water tank.

Preferably, the water tank inlet may be disposed on a top surface of the tank body, and the cold plate outlet and the circulating waterway outlet may be disposed on side surfaces of the tank body.

Preferably, the coolant inlet and the coolant outlet may be respectively disposed on two opposite side surfaces of the cold plate body.

Preferably, the coolant inlet and the coolant outlet may be respectively disposed at two ends of a top surface of the cold plate body.

Preferably, the side pipeline may include a first side pipeline and a second side pipeline, and the first side pipeline and the second side pipeline are respectively connected to different cold plates.

Preferably, the heat exchange chamber may be connected to a heat dissipation plate or a heat dissipation fin.

Preferably, a fan may be provided in the heat exchange chamber.

Preferably, the heat generating component may include a central processing unit or a graphics processing unit of a motherboard.

As described above, the cold plate cooling device according to the present disclosure may have one or more of the following advantages:

(1) By introducing a branching pipe, the present cold plate cooling device may form a negative pressure suction force in the side pipeline at the main pipeline circulation waterway, thereby forming a negative pressure circuit of the cold plate, so that the cold plate device does not need to establish a vacuum environment, reducing the setting cost and also reducing the complexity of the cold plate cooling device assembly.

(2) The present cold plate cooling device may design the position of the water tank and the cold plate so that when cracks appear in the cold plate, the coolant may naturally fall back to the water tank due to gravity, preventing the coolant from leaking and directly contacting the heat generating component, avoiding the problem of short circuit and burnout.

(3) The present cold plate cooling device may simultaneously install multiple cold plates through multiple side pipelines of the branching pipe, thereby increasing the heat dissipation efficiency, increasing the flexibility of the entire design of the electronic device, and improving the overall efficiency.

### BRIEF DESCRIPTION OF THE DRAWINGS

In order to illustrate the technical features, content, advantages and effects of the present disclosure in more detail, the present disclosure is described in detail alongside the embodiments with accompanying drawings as follows:

FIG. 1 is a block diagram of a cold plate cooling device according to an embodiment of the present disclosure.

FIG. 2 is a schematic diagram of the cold plate cooling device of the present disclosure.

FIG. 3 is a schematic diagram of a cold plate according to an embodiment of the present disclosure.

FIG. 4 is a schematic diagram of a cold plate according to another embodiment of the present disclosure.

### DETAILED DESCRIPTION OF THE PREFERRED EMBODIMENTS

To facilitate the understanding of the technical features, content, advantages, and achievable effects of the present disclosure, the present disclosure is described in detail below in conjunction with the accompanying drawings and in the form of embodiments. The figures used therein are intended solely for illustration and to assist in the description, and may not reflect the actual proportions and precise configurations of the present disclosure after implementation. Therefore, it should be understood that the proportions and configurations in the attached figures should not be interpreted to limit the scope of rights of the present disclosure in actual implementation.

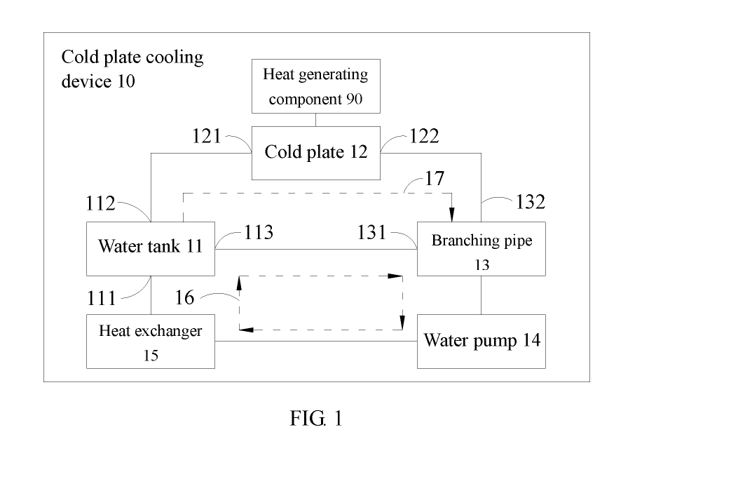

Please refer to FIG. 1, which is a block diagram of a cold plate cooling device according to an embodiment of the present disclosure. As shown in the figure, the cold plate cooling device 10 includes a water tank 11, a cold plate 12, a branching pipe 13, a water pump 14, and a heat exchanger 15. When components within a computer device generate heat during operation, the heat must be cooled and dissipated through various cooling devices to prevent damage to the components due to high temperatures. Among various cooling devices, water cooling using coolant offers excellent heat dissipation and is often chosen for installation in computer devices. For example, in various types of servers, cooling is performed to dissipate heat from heat generating components 90 on each motherboard. Heat generating components 90 include electronic components such as central processing units (CPUs) or graphics processing unit. These electronic components generate significant amounts of heat during operation, requiring cooling through the cold plate cooling device 10 to maintain component performance and ensure the lifespan of the components.

In the cold plate cooling device 10, the cold plate 12 is in contact with the heat generating component 90 to be cooled, and the heat of the heat generating component 90 is taken away by the coolant flowing through the cold plate 12. In order to allow the coolant to flow into and out of the cold plate 12, the existing technology mostly uses a water pump to inject the coolant from the inlet, and uses positive pressure to allow the coolant to flow through the internal pipes of the cold plate 12 and then flow out from the outlet. However, since the cold plate 12 is in direct contact with the heat generating component 90, if the pipes or structures of the cold plate 12 are damaged, the coolant may leak under positive pressure and contact the heat generating component 90, causing the electronic components to short-circuit or open circuit. In view of this problem, the present disclosure adopts a negative pressure method to allow the coolant to be extracted from the outlet. When the cold plate 12 is in a negative pressure state, even if cracks or gaps occur in the structure of the cold plate 12, the coolant will not leak directly and contact the heat generating component 90.

First, the water tank 11 includes a tank body, which is provided with a water tank inlet 111, a cold plate outlet 112, and a circulating waterway outlet 113. The water tank inlet 111 receives the coolant cooled by the heat exchanger 15 and stores the coolant in the tank body. The tank body includes two outlets: the first one is the cold plate outlet 112 connected to the cold plate 12, and the second one is the circulating waterway outlet 113 connected to the branching pipe 13. The circulating waterway outlet 113 is connected to the main pipeline 131 of the branching pipe 13. Since the branching pipe 13 is connected to the water pump 14, when the motor is running, the coolant is continuously pumped out of the branching pipe 13 and sent to the heat exchanger 15 via the water pump 14. After the coolant is cooled at the heat exchanger 15, it is injected through the water tank inlet 111. The coolant flows from the tank body through the circulating waterway outlet 113 to the main pipeline 131, is pumped out by the water pump 14 and sent to the heat exchanger 15, and after cooling, returns to the water tank 11 through the inlet 111 to form a continuous circulating waterway 16.

The cold plate outlet 112 is connected to the coolant inlet 121 of the cold plate 12 so that coolant may enter the cold plate 12 into the flow channel within the cold plate body, and then flow out through the coolant outlet 122 of the cold plate 12 to the side pipeline 132 of the branching pipe 13. As described above, the motor of the water pump 14 continuously operates to form a continuous circulating waterway 16 of the coolant. At this time, coolant in the main pipeline 131 of the branching pipe 13 continuously flows from the water tank 11 toward the water pump 14. The Venturi effect reduces the pressure in the side pipeline 132, generating a negative suction force on the side pipeline 132, drawing the coolant from the cold plate 12 into the branching pipe 13. The coolant flows out of the cold plate outlet 112, flows into the cold plate 12 through the coolant inlet 121, and then flows out of the coolant outlet 122, enters the main pipeline 131 of the branching pipe 13 through the side pipeline 132, and forms a cold plate negative pressure circuit 17.

By providing a continuous circulating waterway 16 and utilizing the Venturi effect of the branching pipe 13 to create a negative pressure state within the side pipeline 132 and the cold plate 12, even if the structure of the cold plate 12 is damaged, the coolant will still be pumped out through the side pipeline and will not flow out through cracks in the cold plate 12 and damage the heat generating components. Furthermore, the cold plate 12 is positioned higher than the water tank 11, allowing the coolant inlet 121 to be higher than the circulating waterway outlet 113 of the water tank 11. In the event of structural damage to the cold plate, the coolant at the coolant inlet 121 will naturally fall back into the water tank 11 due to gravity, preventing the coolant from continuously being injected into the cold plate 12, thereby preventing the coolant from flowing out through cracks in the cold plate 12 and damaging the heat generating component. In this embodiment, the branching pipe 13 utilizes the Venturi effect generated between the main pipeline 131 and the side pipeline 132 to create a negative pressure condition in the side pipeline 132, thereby forming a cold plate negative pressure circuit 17 in the cold plate 12. This design eliminates the need for vacuum equipment to create a negative pressure environment when water is introduced into the cold plate 12 at a negative pressure, effectively reducing the cost and the complexity of manufacturing the cold plate cooling device 10.

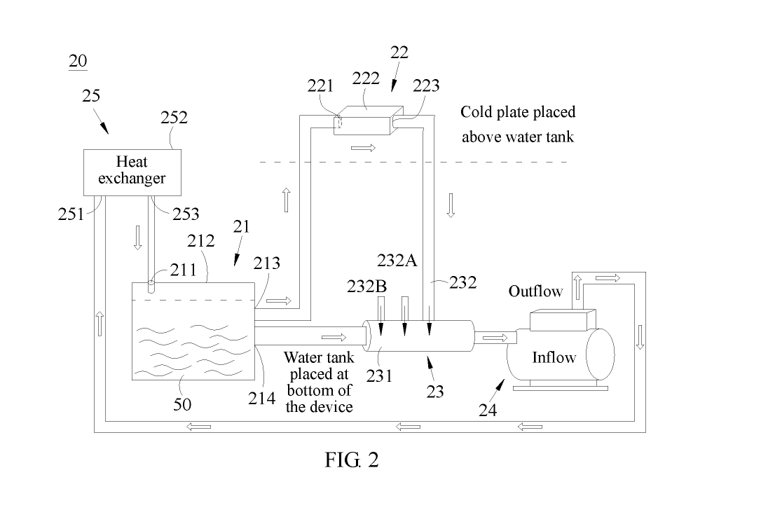

Please refer to FIG. 2, which is a schematic diagram of a cold plate cooling device according to an embodiment of the present disclosure. As shown in the figure, the cold plate cooling device 20 includes a water tank 21, a cold plate 22, a branching pipe 23, a water pump 24, and a heat exchanger 25. The water tank 21 includes a water tank inlet 211, a tank body 212, a cold plate outlet 213, and a circulating waterway outlet 214. The water tank 21 is disposed at the bottom of the cold plate cooling device 20, such that the cold plate 22 and the heat exchanger 25 are disposed at a higher position than the water tank 21. The tank body 212 has an internal space for storing coolant 50, and the external shape of the body may be adjusted according to the internal space of the cooling device. The water tank inlet 211 is disposed on the top surface of the tank body 212, and the cold plate outlet 213 and the circulating waterway outlet 214 are disposed on the side surface of the tank body 212. The cold plate outlet 213 may be disposed above the circulating waterway outlet 214. When multiple cold plates 22 are provided, multiple cold plate outlets 213 may be provided to correspond to the cold plates 22 respectively.

The cold plate 22 includes a coolant inlet 221, a cold plate body 222, and a coolant outlet 223. The cold plate body 222 is in contact with the heat generating component and includes a channel space for the coolant 50 to pass through. When the coolant 50 flows through the cold plate 22, it may dissipate heat from the heat generating component. The coolant inlet 221 is connected to the cold plate outlet 213. The cold plate 22 is positioned higher than the water tank 21 so that when cracks appear in the structure of the cold plate 22 or the negative pressure state is released, the coolant 50 will naturally fall back from the coolant inlet 221 to the cold plate outlet 213 due to gravity and be stored in the tank body 212, thereby preventing leakage in the pipe and damaging other electronic components.

The branching pipe 23 includes a main pipeline 231 and side pipeline 232. The main pipeline 231 has a larger area than the side pipeline 232. The main pipeline 231 communicates with the circulating waterway outlet 214 and is connected to the water pump 24. The motor of the water pump 24 pumps coolant 50 from the circulating waterway outlet 214 through the main pipeline into the water pump 24, and then out of the outlet of the water pump 24, flowing to the hot water inlet of the heat exchanger 25. When the motor of the water pump 24 continues to operate, causing the coolant 50 to continuously flow through the main pipeline 231, the side pipeline 232 of the branching pipe 23 generate negative pressure suction due to the Venturi effect. This causes the coolant 50 in the water tank 21 to flow out of the cold plate outlet 213, into the cold plate body 222 through the coolant inlet 221, and then out of the coolant outlet 223, and into the main pipeline 231 of the branching pipe 23 through the side pipeline 232. The Venturi effect of the branching pipe 23 creates a negative pressure state in the side pipeline 232 and the cold plate 22. Even if the structure of the cold plate 22 is damaged, the coolant 50 will still be pumped out through the side pipeline 232 and will not flow out through the cracks in the cold plate 22 and damage the heat generating component.

In this embodiment, the branching pipe 23 further includes a first side pipeline 232A and a second side pipeline 232B, disposed in parallel with the side pipeline 232. The first side pipeline 232A and the second side pipeline 232B are connected to different cold plates. Similarly, the fluid in the main pipeline 231 of the branching pipe 23 creates a negative pressure suction force in each branch, allowing the coolant 50 to dissipate heat through other cold plates. The number of side pipelines in the present disclosure is not limited to the number shown in the embodiment. In other embodiments, the number of side pipelines and the corresponding number of cold plates may be adjusted based on the type and number of heating components.

The cold plate 22 uses coolant 50 to cool and dissipate heat from the heat generating component. After passing through the cold plate 22, the outflowing coolant 50 has a relatively high temperature. Although it mixes with the coolant 50 from the water tank after entering the main pipeline 231 for initial cooling, the coolant 50 still has a relatively high temperature when passing through the water pump 24 and must be further cooled by the heat exchanger 25 to restore the coolant 50 to a lower operating temperature. The coolant 50 pumped out by the water pump 24 enters the heat exchange chamber 252 of the heat exchanger 25 through the hot water inlet 251. The heat exchange chamber 252 may include an internal cavity space or internal pipes. The heat exchange chamber 252 is connected to a heat dissipation plate or heat dissipation fin, or a fan may be provided in the heat exchange chamber 252 to cool the coolant 50 in the heat exchange chamber 252. The coolant then flows out through the cold water outlet 253 and returns to the tank body 212 through the water tank inlet 211. The heat exchanger 25 is positioned higher than the water tank 21. The cooled coolant 50 may be directly injected into the water tank inlet 211 from the cold water outlet 253 and stored in the tank body 212. The coolant 50 flows from the tank body 212 through the circulating waterway outlet 214 to the main pipeline 231. It is then pumped out by the water pump 24 and sent to the hot water inlet 251. After flowing out of the cold water outlet 253, it returns to the water tank 21 through the water tank inlet 211, forming a continuous circulating waterway. When the continuous circulating waterway flows through the main pipeline 231, a negative pressure is generated in the side pipeline 232, causing the coolant 50 to flow out of the cold plate outlet 213, flow into the cold plate body 222 through the coolant inlet 221, and then flow out of the coolant outlet 223, entering the main pipeline 231 through the side pipeline 232, forming a cold plate negative pressure circuit.

When cracks or damage occur in the cold plate 22, the coolant 50 flows out from both the coolant inlet 221 and the coolant outlet 223. This height difference causes the coolant 50 to fall back to the water tank 21 due to gravity, while the side pipeline 232 draws the coolant 50 out under negative pressure, preventing the coolant 50 from leaking through cracks of the cold plate 22 and damaging the heat generating component. The branching pipe 23 design may correspond to the number of cold plates 22 to be installed, and also simplifies the installation by eliminating the need for vacuum equipment to create a negative pressure environment, effectively reducing installation costs.

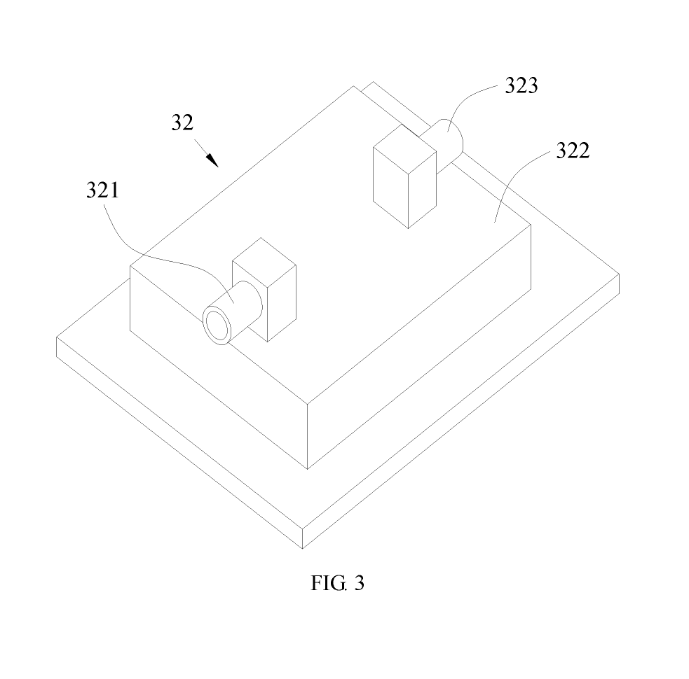

Please refer to FIG. 3, which is a schematic diagram of the cold plate of the present disclosure. As shown in the figure, the cold plate 32 includes a coolant inlet 321, a cold plate body 322, and a coolant outlet 323. The cold plate body 322 may be a metal plate or sheet structure, which contacts the heat generating component and dissipates heat from the heat generating component through the coolant in the cold plate body 322. The coolant inlet 321 and the coolant outlet 323 may be respectively disposed at both ends of the top surface of the cold plate body 322. Please refer to the previous embodiment. The coolant inlet 321 is connected to the cold plate outlet to receive the coolant from the water tank, and the coolant outlet 323 is connected to the side pipeline to send the discharged coolant to the branching pipe.

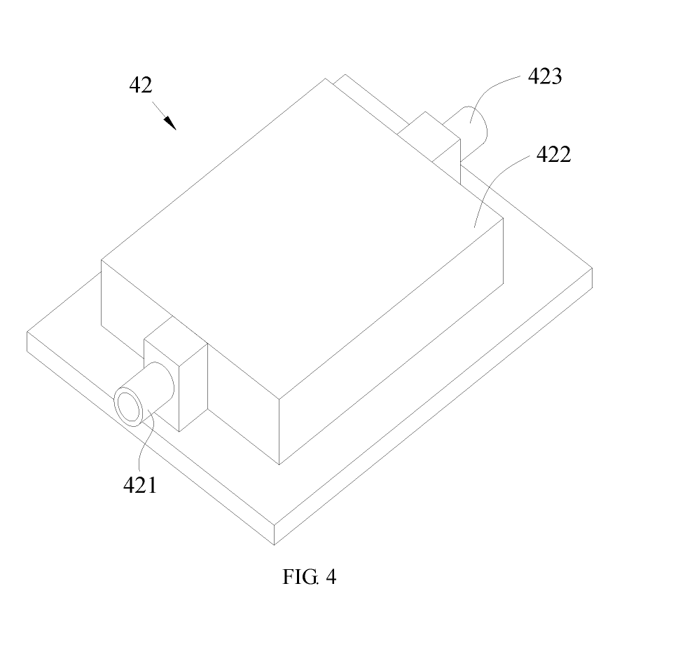

Please refer to FIG. 4, which is a schematic diagram of a cold plate according to another embodiment of the present disclosure. As shown in the figure, the cold plate 42 includes a coolant inlet 421, a cold plate body 422, and a coolant outlet 423. The cold plate body 422 may be a metal plate or sheet structure, which contacts the heat generating component and dissipates heat from the heat generating component through the coolant in the cold plate body 422. The coolant inlet 421 and the coolant outlet 423 may be respectively disposed on two opposite side surfaces of the cold plate body 422. Referring to the previous embodiment, the coolant inlet 421 is connected to the cold plate outlet to receive the coolant from the water tank. The coolant outlet 423 is connected to the side pipeline to send the discharged coolant to the branching pipe.

The above description is for illustrative purposes only and is not intended to be limiting. Any equivalent modifications or changes made thereto without departing from the spirit and scope of this invention shall be included in the scope of the patent application appended hereto.

What is claimed is:

1. A cold plate cooling device, comprising:
a water tank comprising a water tank inlet, a tank body, a cold plate outlet and a circulating waterway outlet;
a cold plate comprising a coolant inlet, a cold plate body, and a coolant outlet, wherein the cold plate body is in contact with a heat generating component, and a coolant in the cold plate body dissipates heat from the heat generating component, the coolant inlet is connected to the cold plate outlet, and the cold plate is positioned higher than the water tank;
a branching pipe comprising a main pipeline and a side pipeline, wherein the main pipeline is connected to the circulating waterway outlet, and the side pipeline is connected to the coolant outlet;
a water pump connected to the main pipeline; and
a heat exchanger comprising a hot water inlet, a heat exchange chamber and a cold water outlet, wherein the hot water inlet is connected to the water pump, and the cold water outlet is connected to the water tank inlet;
wherein, the coolant flows out from the tank body through the circulating waterway outlet to the main pipeline, being pumped out by the water pump and sent to the hot water inlet, and then flows out from the cold water outlet and returns to the water tank through the water tank inlet, forming a continuous circulating waterway, and when the continuous circulating waterway flows through the main pipeline, negative pressure is generated in the side pipeline so that the coolant flows out from the cold plate outlet, flows into the cold plate body through the coolant inlet, and then flows out from the coolant outlet and enters the main pipeline through the side pipeline, forming a cold plate negative pressure circuit.

2. The cold plate cooling device of claim 1, wherein the water tank is disposed at a bottom of the cold plate cooling device.

3. The cold plate cooling device of claim 1, wherein the heat exchanger is disposed at a higher position than the water tank.

4. The cold plate cooling device of claim 1, wherein the water tank inlet is disposed on a top surface of the tank body, and the cold plate outlet and the circulating waterway outlet are disposed on side surfaces of the tank body.

5. The cold plate cooling device of claim 1, wherein the coolant inlet and the coolant outlet are respectively disposed on two opposite side surfaces of the cold plate body.

6. The cold plate cooling device of claim 1, wherein the coolant inlet and the coolant outlet are respectively disposed at two ends of a top surface of the cold plate body.

7. The cold plate cooling device of claim 1, wherein the side pipeline includes a first side pipeline and a second side pipeline, and the first side pipeline and the second side pipeline are respectively connected to different cold plates.

8. The cold plate cooling device of claim 1, wherein the heat exchange chamber is connected to a heat dissipation plate or a heat dissipation fin.

9. The cold plate cooling device of claim 1, wherein the heat exchange chamber is provided with a fan.

10. The cold plate cooling device of claim 1, wherein the heat generating component includes a central processing unit or a graphics processing unit of a motherboard.
